(19) United States
(12) Patent Application Publication
(10) Pub. No.: US 2026/0136638 A1
(43) Pub. Date: May 14, 2026

(54) METHOD FOR FABRICATING INTEGRATED STRUCTURE OF METAL-GATE MOS TRANSISTOR

(71) Applicant: Shanghai Huali Integrated Circuit Corporation, Shanghai (CN)

(72) Inventors: Xiaoliang TANG, Shanghai (CN); Qiwei WANG, Shanghai (CN); Haoyu CHEN, Shanghai (CN)

(73) Assignee: Shanghai Huali Integrated Circuit Corporation, Shanghai (CN)

(21) Appl. No.: 19/279,334

(22) Filed: Jul. 24, 2025

(30) Foreign Application Priority Data
Nov. 13, 2024 (CN) 202411622781.8

(51) Int. Cl. H10D 84/01; H10D 84/83

(52) U.S. Cl. CPC H10D 84/014; H10D 84/013; H10D 84/0149; H10D 84/0151; H10D 84/83135

(57) ABSTRACT

The present disclosure discloses a method for fabricating an integrated structure of a metal-gate MOS transistor, which defines a high-resistance MOS device gate structure region in the high-resistance device area and a high-voltage MOS device gate structure region in the high-voltage device area through photolithography, wherein during gate polysilicon etching, the entire high-voltage MOS device gate structure region is retained without forming slots in the MOS device gate structure regions; spacers are formed through self-aligned etching, eliminating the need for a spacers process mask; and the same mask layer is used for both the high-resistance layer etching and the slot etching in the high-voltage MOS device gate structure region. This fabricating method offers several advantages: reduced number of required masks, healthier high-voltage MOS device gate structures, larger process windows, improved device electrical characteristics, enhanced reliability, and simplified contact hole etching process with lower contact resistance.

### CROSS-REFERENCE TO RELATED APPLICATIONS

This application claims priority to Chinese patent application No. 202411622781.8 filed on Nov. 13, 2024, the disclosure of which is incorporated herein by reference in its entirety.

### TECHNICAL FIELD

The present disclosure relates to semiconductor fabricating technology, particularly to a method for fabricating an integrated structure of a metal-gate MOS transistor.

### BACKGROUND

From the 28 nm node and beyond, high performance processes employ high dielectric constant (High-K, HK) materials combined with metal-gates to enhance device performance. In 28HV (28 nm high voltage) technology, low-voltage, medium voltage, and high-voltage devices all adopt the HKMG (High-K Metal-gate) process. However, large area high-voltage gates can lead to metal-gate dishing during chemical mechanical polishing (CMP) (referring to FIG. 1). To mitigate this, oxide slots are introduced within the metal-gate to prevent dishing during CMP. Additionally, an extra spacer process mask is required to protect the oxide in the HV metal-gate slots from subsequent spacer processes, which could otherwise cause potential reliability failures.

The 28HV HKMG process features a low metal-gate resistance (less than 30 ohm/sqr), requiring an additional high resistivity process before contact hole (CT) formation to achieve high-resistance gates. This high resistivity process introduces an independent mask along with corresponding lithography and etching steps.

In conventional fabricating methods for metal-gate MOS transistor integrated structures, two masks—a spacer process mask and a high resistivity (HiR) layer mask—are required to meet the reliability demands of high-voltage devices and the high-resistance gate requirements of MOS transistors. Moreover, during the formation of high-voltage metal-gate slots, a polysilicon etching process must be performed on the central region of the high-voltage MOS gate structure, which may compromise device reliability. Furthermore, to achieve high-resistance gates for high-resistance MOS devices, an interlayer dielectric (ILD) and a high resistivity (HiR) layer must be sequentially deposited over the gate polysilicon. Since the ILD is relatively thick, the contact hole (CT) length over the active area (AA) increases, The length of the contact hole (CT) on the active region (AA) increases, which makes the etching of the contact hole (CT) more difficult and the resistance of the contact hole (CT) increases.

### BRIEF SUMMARY

The method fabricating for the integrated structure of a metal-gate MOS transistor provided by the disclosure comprises the following steps:
S1. performing an active region process on a silicon substrate 100, dividing the silicon substrate 100 into a high-voltage device region 101 and a high-resistance device region 102 by shallow trench isolation 104, wherein a pad oxide layer 105 covers the silicon substrate 100 in both the high-voltage device region 101 and the high-resistance device region 102;
S2. depositing a gate polysilicon layer 106, and then coating a first photoresist 107;
S3. performing photolithography to define a high-resistance MOS device gate structure region in the high-resistance device region 102 and a high-voltage MOS device gate structure region in the high-voltage device region 101, etching to remove the gate polysilicon layer 106 and the pad oxide layer 105 in regions outside the gate structure regions, thereby exposing the silicon substrate 100 and the upper surface of the shallow trench isolation 104, while retaining the gate polysilicon layer 106 and the pad oxide layer 105 in the entirety of high-resistance MOS device gate structure region and the high-voltage MOS device gate structure region;
S4. removing the first photoresist 107 and forming a spacer dielectric layer 108;
S5. performing self aligned etching on the spacer dielectric layer 108 to expose the upper surface of the gate polysilicon layer 106 and the upper surfaces of the silicon substrate 100 and the shallow trench isolation 104 between the spacers, thereby forming spacers for the high-resistance MOS device gate structure and the high-voltage MOS device gate structure;
S6. forming a first interlayer dielectric layer 109, followed by chemical mechanical polishing to expose the gate polysilicon layer 106 of the high-resistance MOS device gate structure and the high-voltage MOS device gate structure; S8. depositing a high-resistance layer 110;
S9. coating a second photoresist 111, performing photolithography to define the high-resistance MOS device gate structure and its spacer region, and defining a plurality of spaced apart high-voltage MOS device gate sub-structure regions on the high-voltage MOS device gate structure;
S10, etching to remove the high-resistance layer 110 outside the high-resistance MOS device gate structure and its spacer region and outside each high-voltage MOS device gate sub-structure region, and removing the gate polysilicon layer 106 outside the high-resistance MOS device gate structure and each high-voltage MOS device gate sub-structure region, thereby exposing the pad oxide layer 105 and forming a plurality of high-voltage MOS device gate sub-structures separated by narrow slots in the high-voltage MOS device gate structure region;
S11. removing the second photoresist 111, depositing a gate metal layer 112, and then performing chemical mechanical polishing until it is flush with the high-resistance layer 110;
S12. forming a second interlayer dielectric layer 113;
S13. forming contact holes 114, wherein the lower end of the contact hole of the high-resistance MOS device connects to the top surface of the high-resistance layer 110 on the high-resistance MOS device gate structure.

According to some embodiments of the present disclosure, after step S6, step S7 is performed, wherein wet etching removes the top portion of the gate polysilicon layer 106 of the high-resistance MOS device gate structure and the high-voltage MOS device gate structure, followed by step S8.

According to some embodiments of the present disclosure, in step S1, the silicon substrate 100 is divided by shallow trench isolation 104 into a high-voltage device region 101, a high-resistance device region 102, and a low-voltage device region 103; the silicon substrate 100 in the high-voltage device region 101, the high-resistance device region 102, and the low-voltage device region 103 is covered with a pad oxide layer 105;

In step S3, photolithography further defines a low-voltage MOS device gate structure region in the low-voltage device region 103, and etching removes the gate polysilicon layer 106 and the pad oxide layer 105 in regions outside the gate structure regions, exposing the silicon substrate 100 and the upper surface of the shallow trench isolation 104, while retaining the gate polysilicon layer 106 and the pad oxide layer 105 in the entirety of the low-voltage MOS device gate structure region, the high-resistance MOS device gate structure region, and the high-voltage MOS device gate structure region;

In step S5, spacers are formed for the low-voltage MOS device gate structure, the high-resistance MOS device gate structure, and the high-voltage MOS device gate structure;

In step S6, after chemical mechanical polishing, the gate polysilicon layer 106 of the low-voltage MOS device gate structure, the high-resistance MOS device gate structure, and the high-voltage MOS device gate structure is exposed;

In step S7, wet etching removes the top portion of the gate polysilicon layer 106 of the low-voltage MOS device gate structure, the high-resistance MOS device gate structure, and the high-voltage MOS device gate structure;

In step S9, photolithography defines the low-voltage MOS device gate structure and its spacer region, the high-resistance MOS device gate structure and its spacer region, and a plurality of spaced-apart high-voltage MOS device gate sub-structure regions on the high-voltage MOS device gate structure;

In step S10, etching removes the high-resistance layer 110 outside the low-voltage MOS device gate structure and its spacer region, the high-resistance MOS device gate structure and its spacer region, and each high-voltage MOS device gate sub-structure region, and removes the gate polysilicon layer 106 outside the low-voltage MOS device gate structure, the high-resistance MOS device gate structure, and each high-voltage MOS device gate sub-structure region, thereby exposing the pad oxide layer 105 and forming a plurality of high-voltage MOS device gate sub-structures separated by narrow slots in the high-voltage MOS device gate structure region.

According to some embodiments of the present disclosure, in step S5, after forming the spacers of the low-voltage MOS device gate structure, the high-resistance MOS device gate structure, and the high-voltage MOS device gate structure, lightly doped drain 120 ion implantation is performed for the low-voltage MOS device and the high-resistance MOS device.

According to some embodiments of the present disclosure, the operating voltage of the low-voltage MOS device is less than 2V.

According to some embodiments of the present disclosure, the high-resistance MOS device is a medium voltage MOS device, and the operating voltage of the medium voltage MOS device is 6V-10V.

According to some embodiments of the present disclosure, the operating voltage of the high-voltage MOS device is 20V-32V.

According to some embodiments of the present disclosure, in step S1, a high-voltage silicon recess is formed in the upper portion of the silicon substrate 100 in the high-voltage device region 101 and filled with an oxide;
a medium-voltage silicon recess is formed in the upper portion of the silicon substrate 100 in the high-resistance device region 102 and filled with an oxide;
the depth of the medium voltage silicon recess in the silicon substrate 100 is less than that of the high-voltage silicon recess in the silicon substrate 100;
the pad oxide layer 105 covers the silicon substrate 100 and the oxide in the silicon recesses.

According to some embodiments of the present disclosure, the depth of the high-voltage silicon recess in the silicon substrate 100 is 400 Å to 500 Å;
the depth of the medium voltage silicon recess in the silicon substrate 100 is 100 Å to 200 Å.

According to some embodiments of the present disclosure, in step S12, the second interlayer dielectric layer is formed by in-situ steam generation and thermal oxidation.

According to some embodiments of the present disclosure, the high-resistance layer is made of titanium nitride, tantalum nitride, or tungsten nitride.

The method for fabricating the integrated structure of the metal-gate MOS transistor according to the present disclosure defines the high-resistance MOS device gate structure region in the high-resistance device region 102 and the high-voltage MOS device gate structure region in the high-voltage device region 101 through photolithography. During gate polysilicon etching, the entire high-voltage MOS device gate structure region is preserved without forming slots in the MOS device gate structure region. The spacers are formed through self-aligned etching, eliminating the need for a spacers process mask. The etching of the high-resistance (HiR) layer 110 and the slot etching in the high-voltage MOS device gate structure region are performed using the same mask layer.

This fabricating method, through adjustments to existing processes, can reduce the total number of masks required by one layer. Simultaneously, through structural modifications, the underlying pad oxide layer 105 of the high-voltage device remains continuously covered throughout the entire process, resulting in healthier high-voltage MOS device gate structures that are unaffected by process variations, a wider process window, improved device electrical characteristics, and higher reliability. Additionally, this fabricating method eliminates the need to sequentially form an interlayer dielectric (ILD) layer and a high-resistance (HiR) layer above the gate polysilicon of the high-resistance MOS device. The thickness of the ILD layer can be reduced, making the contact hole (CT) etching process simpler and resulting in lower contact resistance, thereby providing electrical performance advantages.

### BRIEF DESCRIPTION OF THE DRAWINGS

To provide a clearer explanation of the technical solutions of the present disclosure, the following briefly introduces the accompanying drawings required for illustrating the disclosure. Obviously, the drawings in the following description represent only some embodiments of the disclosure. For those skilled in the art, other drawings may be derived from these illustrations without creative effort.

FIGS. 1 to 13 are schematic cross-sectional diagrams illustrating the fabricating process of an embodiment of the integrated structure of the metal-gate MOS transistor according to the present invention.

### EXPLANATION OF REFERENCE NUMERALS

100: silicon substrate; 101: high-voltage device region; 102: high-resistance device region; 103: low-voltage device region; 104: shallow trench isolation; 105: pad oxide layer; 106: gate polysilicon layer; 107: first photoresist; 108: spacer dielectric layer; 109: first interlayer dielectric layer; 110: high-resistance layer; 111: second photoresist; 112: gate metal layer; 113: second interlayer dielectric layer; 114: contact hole; 120: LDD.

### DETAILED DESCRIPTION OF THE DISCLOSURE

The technical solutions in the embodiments of the present disclosure will be clearly and completely described below with reference to the accompanying drawings. Obviously, the described embodiments represent only some embodiments of the present disclosure rather than all possible implementations. All other embodiments obtained by persons of ordinary skill in the art based on the embodiments of the present disclosure without creative efforts shall fall within the protection scope of the present disclosure.

The words “first”, “second” and similar expressions used in this disclosure do not indicate any order, quantity or importance, but only to distinguish the different components. Words such as “include” or “comprise” mean that the element or object preceding the word includes the element or object listed after the word and its equivalents, and does not exclude other elements or objects. Similar terms such as “connection” or “couple” are not limited to physical or mechanical connections, but may include electrical connections, whether direct or indirect. “up”, “down”, “left”, “right”, “front”, “back”, etc., are only used to indicate the relative positional relationship, and when the absolute position of the described object changes, the relative positional relationship may also change accordingly.

It should be noted that, in cases of no conflict, the embodiments of the present disclosure and the features in the embodiments may be combined with each other.

### Embodiment 1

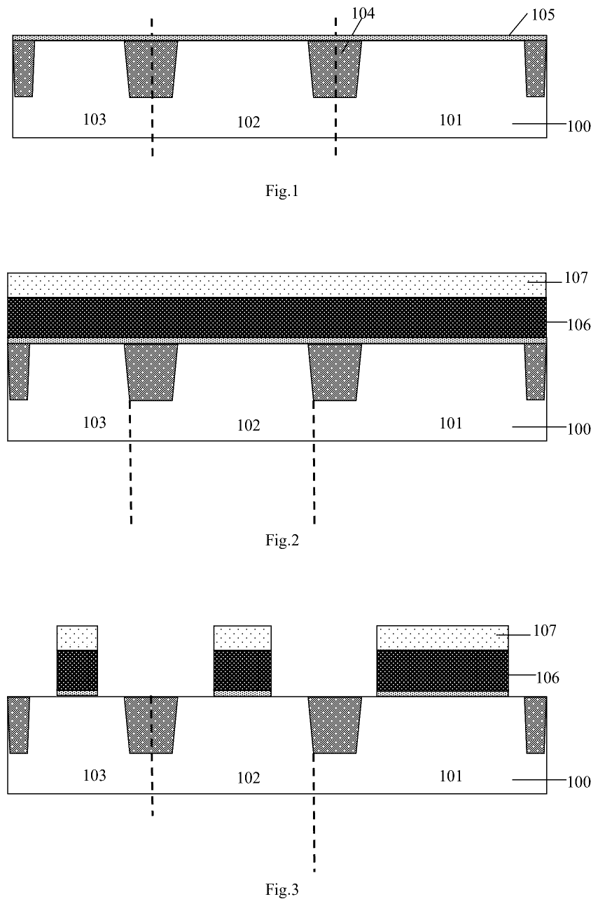

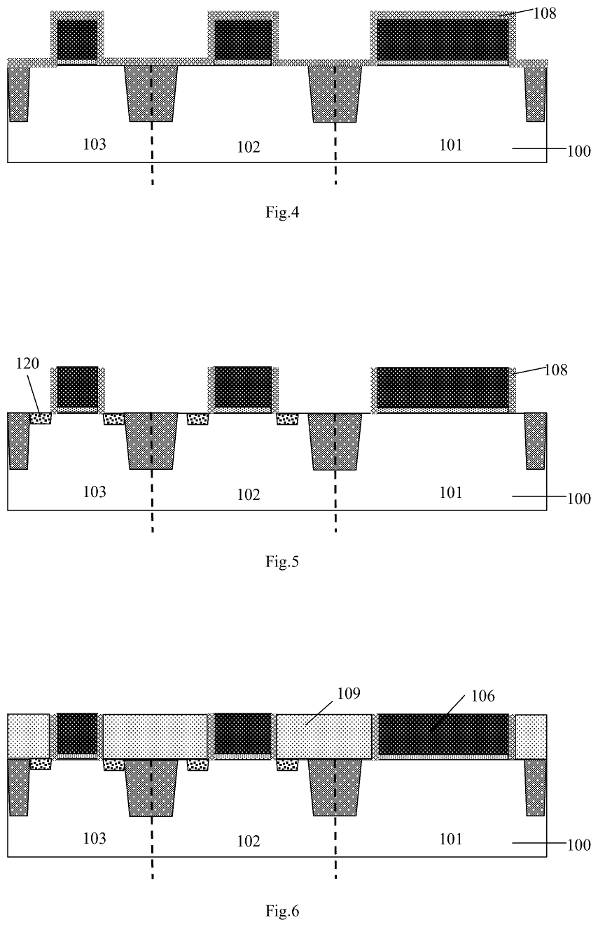

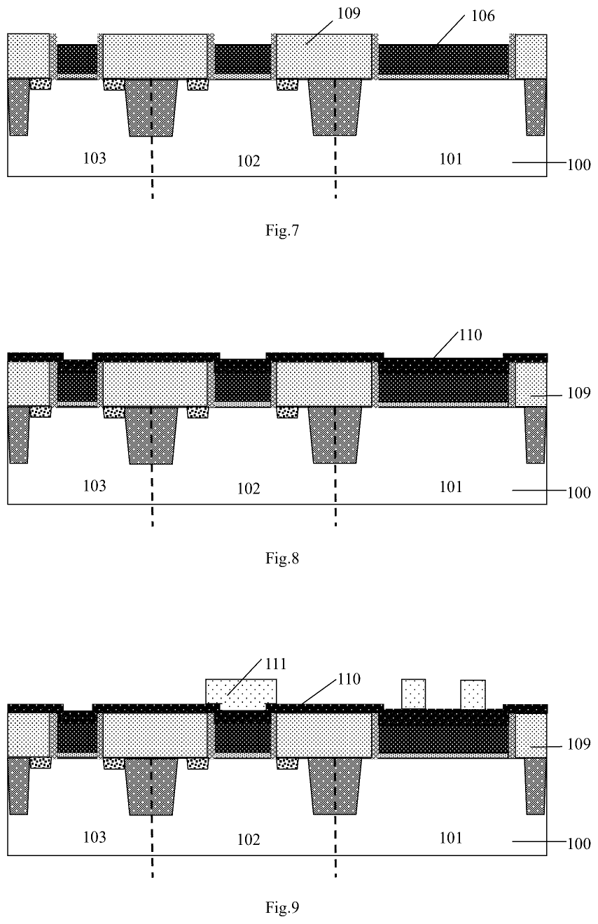

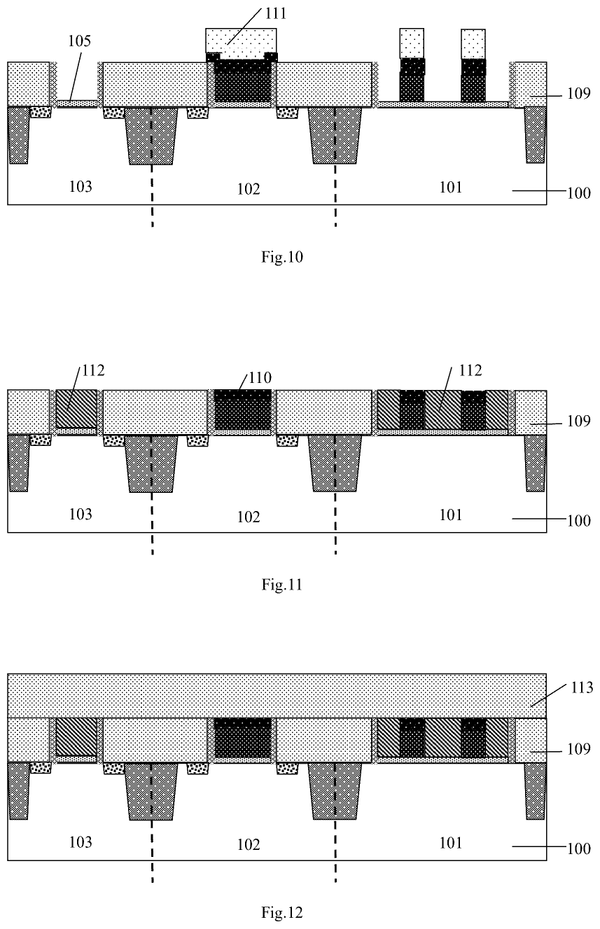

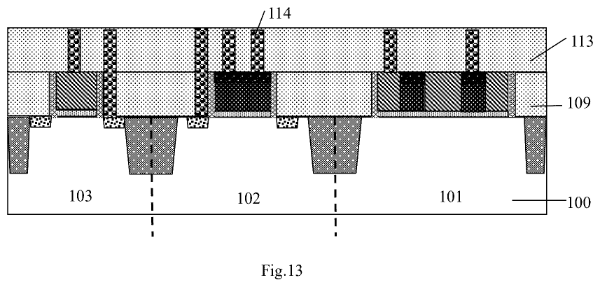

A method for fabricating an integrated structure of a metal-gate MOS transistor includes the following steps:
S1. The active region (AA) process is performed on the silicon substrate 100, so that the silicon substrate 100 is divided into high-voltage device region 101 and high-resistance device region 102 by shallow trench isolation (STI) 104; the silicon substrate 100 of the high-voltage device region 101 and the high-resistance device region 102 are covered with a pad oxide layer 105, referring to FIG. 1;
S2. A gate polycrystalline silicon layer 106 is deposited, and then a first photoresist 107 is coated, referring to FIG. 2;
S3. Photolithography is performed to define a high-resistance MOS device gate structure region in the high-resistance device region 102 and a high-voltage MOS device gate structure region in the high-voltage device region 101. The gate polysilicon layer 106 and pad oxide layer 105 in areas outside the gate structure regions are etched away to exposes the silicon substrate 100 and the upper surface of the shallow trench isolation 104, while retaining the gate polysilicon layer 106 and the pad oxide layer 105 in the entirety of the high-resistance MOS device gate structure region and the high-voltage MOS device gate structure region, referring to FIG. 3;
S4. A first photoresist 107 is removed, and a spacer dielectric layer 108 is formed, referring to FIG. 4;
S5. Self-aligned etching is performed on the spacer dielectric layer 108 to expose the upper surface of the gate polysilicon layer 106, and the silicon substrate 100 and the upper surface of the shallow trench isolation (STI) 104 between the spacers, and spacers for both the high-resistance MOS device gate structure and the high-voltage MOS device gate structure are formed, referring to FIG. 5;
S6. A first interlayer dielectric layer 109 is formed, followed by chemical mechanical polishing (CMP) to expose the gate polysilicon layer 106 of both the high-resistance MOS device gate structure and the high-voltage MOS device gate structure, referring to FIG. 6;
S7. Wet etching is performed to remove the top portion of the gate polysilicon layer 106 in both the high-resistance MOS device gate structure and the high-voltage MOS device gate structure, referring to FIG. 7;
S8. A high-resistance (HiR) layer 110 is deposited, referring to FIG. 8;
S9. A second photoresist 111 is coated, and photolithography is performed to define the high-resistance MOS device gate structure and its spacer region, while a plurality of spaced-apart high-voltage MOS device gate sub-structure regions are defined on the high-voltage MOS device gate structure, referring to FIG. 9;
S10. An etching process is performed to remove the high-resistance (HiR) layer 110 outside the high-resistance MOS device gate structure and its spacer region as well as outside each high-voltage MOS device gate sub-structure region. The gate polysilicon layer 106 outside the high-resistance MOS device gate structure and each high-voltage MOS device gate sub-structure region is also removed, thereby exposing the pad oxide layer 105. A plurality of high-voltage MOS device gate sub-structures separated by slots are formed in the high-voltage MOS device gate structure region, referring to FIG. 10;
S11. The second photoresist 111 is removed, followed by deposition of a gate metal layer 112. Chemical mechanical polishing (CMP) is then performed until the surface is flush with the high-resistance (HiR) layer 110, referring to FIG. 11;
S12. A second interlayer dielectric layer 113 is formed, referring to FIG. 12;
S13. Contact holes (CT) 114 are formed, with the lower ends of the contact holes for the high-resistance MOS device connecting to the top surface of the high-resistance (HiR) layer 110 on the high-resistance MOS device gate structure, referring to FIG. 13.

The method for fabricating the integrated structure of the metal-gate MOS transistor in Embodiment 1 defines both the high-resistance MOS device gate structure region in the high-resistance device region 102 and the high-voltage MOS device gate structure region in the high-voltage device region 101 through photolithography. During the gate polysilicon etching process, the entire high-voltage MOS device gate structure region is retained without forming slots in the MOS device gate structure region. Spacers are formed through self-aligned etching, eliminating the need for a spacer process mask. Both the etching of the high-resistance (HiR) layer 110 and the slot etching in the high-voltage MOS device gate structure region are performed using the same mask layer.

The fabricating method of Embodiment 1 reduces the total number of required masks by one through adjustments to existing processes. Meanwhile, structural modifications ensure that the underlying pad oxide layer 105 of high-voltage devices remains continuously covered throughout the entire fabricating process. This results in healthier high-voltage MOS device gate structures that are unaffected by process variations, provides a wider process window, delivers superior device electrical characteristics, and achieves higher reliability.

Furthermore, this fabricating method eliminates the need to sequentially form an interlayer dielectric (ILD) layer and a high-resistance (HiR) layer above the gate polysilicon of high-resistance MOS devices. The thickness of the ILD layer can be reduced, which simplifies the contact hole (CT) etching process and lowers contact resistance, thereby providing significant electrical performance advantages.

### Embodiment 2

According to the fabricating method of the integrated structure of the metal-gate MOS transistor based on Embodiment 1, in Step S1: the silicon substrate 100, which is divided by shallow trench isolation (STI) 104 into a high-voltage device region 101, a high-resistance device region 102, and a low-voltage device region 103, is covered with a pad oxide layer 105 in these regions, referring to FIG. 1;
in Step S3: the gate structure region for the low-voltage MOS device in the low-voltage device region 103 is defined by photolithography. The gate polysilicon layer 106 and pad oxide layer 105 outside the gate structure region are etched away, exposing the surface of the silicon substrate 100 and the shallow trench isolation (STI) 104, while retaining the gate polysilicon layer 106 and the pad oxide layer 105 in the entirety of the low-voltage MOS device gate structure region, the high-resistance MOS device gate structure region, and the high-voltage MOS device gate structure region, referring to FIG. 3;
in Step S5: spacers of the low-voltage MOS gate structure, high-resistance MOS gate structure, and high-voltage MOS gate structure are formed, referring to FIG. 5;
in Step S6: after chemical mechanical polishing (CMP), the gate polysilicon layer 106 of the low-voltage MOS gate structure, high-resistance MOS gate structure, and high-voltage MOS gate structure is exposed, referring to FIG. 6;
in Step S7: a wet etching process is performed to remove the top portion of the gate polysilicon layer 106 in the low-voltage MOS gate structure, high-resistance MOS gate structure, and high-voltage MOS gate structure, referring to FIG. 7;
in Step S9: photolithography defines the low-voltage MOS gate structure and its spacer region, the high-resistance MOS gate structure and its spacer region, and defines a plurality of spaced-apart high-voltage MOS gate sub-structure regions of the high-voltage MOS gate structure, referring to FIG. 9;
in Step S10: etching is performed to remove the high-resistance layer 110 outside the low-voltage MOS gate structure and its spacer region, high-resistance MOS gate structure and its spacer region, and each high-voltage MOS gate sub-structure region, and the gate polysilicon layer 106 outside the low-voltage MOS gate structure, high-resistance MOS gate structure, and each high-voltage MOS gate sub-structure region, exposing the pad oxide layer 105, thus a plurality of high-voltage MOS gate sub-structures separated by slots are formed in the high-voltage MOS gate structure region, referring to FIG. 10.

According to some embodiments, in Step S5, spacers for the low-voltage MOS gate structure, high-resistance MOS gate structure, and high-voltage MOS gate structure are formed, then lightly doped drain (LDD) ion implantation 120 for the low-voltage MOS device and high-resistance MOS device is performed, referring to FIG. 5.

According to some embodiments, the operating voltage of the low-voltage MOS device should meet the requirements of low voltage (less than 2V, e.g., less than 1 volt or between 1 volt and 2 volts) and high speed.

According to some embodiments, the high-resistance MOS device is a medium-voltage (MV) MOS device with an operating voltage range of 6V-10V, which can be used in current drive circuits.

According to some embodiments, the high-voltage (HV) MOS device has an operating voltage range of 20V-32V.

### Embodiment 3

Based on the fabricating method of the metal-gate MOS transistor integrated structure according to Embodiment 1, in Step S1: a high-voltage silicon recess (Si-Recess) is formed in the upper portion of the silicon substrate 100 of the high-voltage device region 101 and filled with an oxide; a medium-voltage silicon recess (Si-Recess) is formed in the upper portion of the silicon substrate 100 of the high-resistance device region 102 and filled with an oxide;
the depth of the medium-voltage silicon recess in the silicon substrate 100 is shallower than that of the high-voltage silicon recess in the silicon substrate 100;
the pad oxide layer 105 covers both the silicon substrate 100 and the oxide within the silicon recess (Si-Recess).

According to some embodiments, the high-voltage silicon recess (Si-Recess) in the silicon substrate 100 has a depth of approximately 400 Å to 500 Å (e.g., 460 Å);
the medium-voltage silicon recess (Si-Recess) in the silicon substrate 100 has a depth of approximately 100 Å to 200 Å (e.g., 150 Å).

According to some embodiments, in Step S12, the second interlayer dielectric 113 is formed through in-situ steam generation (ISSG) and thermal oxidation.

According to some embodiments, the high-resistance (HiR) material may be selected from titanium nitride (TiN), tantalum nitride (TaN), tungsten nitride (W2N, WN, WN2, or mixtures thereof), etc.

The above descriptions represent only preferred embodiments of the present disclosure and are not intended to limit the scope of the disclosure. Any modifications, equivalent substitutions, or improvements made within the spirit and principles of the present invention shall be included within the protection scope of the present invention.

What is claimed is:

1. A method for fabricating an integrated structure of a metal-gate MOS transistor, comprising the following steps:
S1. performing an active region process on a silicon substrate (100), dividing the silicon substrate (100) into a high-voltage device region (101) and a high-resistance device region (102) by shallow trench isolation (104), wherein a pad oxide layer (105) covers the silicon substrate (100) in both the high-voltage device region (101) and the high-resistance device region (102);
S2. depositing a gate polysilicon layer (106), and then coating a first photoresist (107);
S3. performing photolithography to define a high-resistance MOS device gate structure region in the high-resistance device region (102) and a high-voltage MOS device gate structure region in the high-voltage device region (101), etching to remove the gate polysilicon layer (106) and the pad oxide layer (105) in regions outside the gate structure regions, thereby exposing the silicon substrate (100) and the upper surface of the shallow trench isolation (104), while retaining the gate polysilicon layer (106) and the pad oxide layer (105) in the entirety of high-resistance MOS device gate structure region and the high-voltage MOS device gate structure region;
S4. removing the first photoresist (107) and forming a spacer dielectric layer (108);
S5. performing self-aligned etching on the spacer dielectric layer (108) to expose the upper surface of the gate polysilicon layer (106) and the upper surfaces of the silicon substrate (100) and the shallow trench isolation (104) between the spacers, thereby forming spacers for the high-resistance MOS device gate structure and the high-voltage MOS device gate structure;
S6. forming a first interlayer dielectric layer (109), followed by chemical mechanical polishing to expose the gate polysilicon layer (106) of the high-resistance MOS device gate structure and the high-voltage MOS device gate structure;
S8. depositing a high-resistance layer (110);
S9. coating a second photoresist (111), performing photolithography to define the high-resistance MOS device gate structure and its spacer region, and defining a plurality of spaced-apart high-voltage MOS device gate sub-structure regions on the high-voltage MOS device gate structure;
S10, etching to remove the high-resistance layer (110) outside the high-resistance MOS device gate structure and its spacer region and outside each high-voltage MOS device gate sub-structure region, and removing the gate polysilicon layer (106) outside the high-resistance MOS device gate structure and each high-voltage MOS device gate sub-structure region, thereby exposing the pad oxide layer (105) and forming a plurality of high-voltage MOS device gate sub-structures separated by narrow slots in the high-voltage MOS device gate structure region;
S11. removing the second photoresist (111), depositing a gate metal layer (112), and then performing chemical mechanical polishing until it is flush with the high-resistance layer (110);
S12. forming a second interlayer dielectric layer (113);
S13. forming contact holes (114), wherein the lower end of the contact hole of the high-resistance MOS device connects to the top surface of the high-resistance layer (110) on the high-resistance MOS device gate structure.

2. The method for fabricating the integrated structure of a metal-gate MOS transistor according to claim 1, wherein
after step S6, step S7 is performed, wherein wet etching removes the top portion of the gate polysilicon layer (106) of the high-resistance MOS device gate structure and the high-voltage MOS device gate structure, followed by step S8.

3. The method for fabricating the integrated structure of a metal-gate MOS transistor according to claim 2, wherein
in step S1, the silicon substrate (100) is divided by shallow trench isolation (104) into a high-voltage device region (101), a high-resistance device region (102), and a low-voltage device region (103); the silicon substrate (100) in the high-voltage device region (101), the high-resistance device region (102), and the low-voltage device region (103) is covered with a pad oxide layer (105);
in step S3, photolithography further defines a low-voltage MOS device gate structure region in the low-voltage device region (103), and etching removes the gate polysilicon layer (106) and the pad oxide layer (105) in regions outside the gate structure regions, exposing the silicon substrate (100) and the upper surface of the shallow trench isolation (104), while retaining the gate polysilicon layer (106) and the pad oxide layer (105) in the entirety of the low-voltage MOS device gate structure region, the high-resistance MOS device gate structure region, and the high-voltage MOS device gate structure region;
in step S5, spacers are formed for the low-voltage MOS device gate structure, the high-resistance MOS device gate structure, and the high-voltage MOS device gate structure;
in step S6, after chemical mechanical polishing, the gate polysilicon layer (106) of the low-voltage MOS device gate structure, the high-resistance MOS device gate structure, and the high-voltage MOS device gate structure is exposed;
in step S7, wet etching removes the top portion of the gate polysilicon layer (106) of the low-voltage MOS device gate structure, the high-resistance MOS device gate structure, and the high-voltage MOS device gate structure;
in step S9, photolithography defines the low-voltage MOS device gate structure and its spacer region, the high-resistance MOS device gate structure and its spacer region, and a plurality of spaced-apart high-voltage MOS device gate sub-structure regions on the high-voltage MOS device gate structure;
in step S10, etching removes the high-resistance layer (110) outside the low-voltage MOS device gate structure and its spacer region, the high-resistance MOS device gate structure and its spacer region, and each high-voltage MOS device gate sub-structure region, and removes the gate polysilicon layer (106) outside the low-voltage MOS device gate structure, the high-resistance MOS device gate structure, and each high-voltage MOS device gate sub-structure region, thereby exposing the pad oxide layer (105) and forming a plurality of high-voltage MOS device gate sub-structures separated by narrow slots in the high-voltage MOS device gate structure region.

4. The method for fabricating the integrated structure of a metal-gate MOS transistor according to claim 3, wherein
in step S5, after forming the spacers of the low-voltage MOS device gate structure, the high-resistance MOS device gate structure, and the high-voltage MOS device gate structure, lightly doped drain (120) ion implantation is performed for the low-voltage MOS device and the high-resistance MOS device.

5. The method for fabricating the integrated structure of a metal-gate MOS transistor according to claim 3, wherein
the operating voltage of the low-voltage MOS device is less than 2V.

6. The method for fabricating the integrated structure of a metal-gate MOS transistor according to claim 3, wherein
the high-resistance MOS device is a medium-voltage MOS device, and the operating voltage of the medium-voltage MOS device is 6V-10V.

7. The method for fabricating the integrated structure of a metal-gate MOS transistor according to claim 3, wherein
the operating voltage of the high-voltage MOS device is 20V-32V.

8. The method for fabricating the integrated structure of a metal-gate MOS transistor according to claim 3, wherein
in step S1, a high-voltage silicon recess is formed in the upper portion of the silicon substrate (100) in the high-voltage device region (101) and filled with an oxide;
a medium-voltage silicon recess is formed in the upper portion of the silicon substrate (100) in the high-resistance device region (102) and filled with an oxide;
the depth of the medium-voltage silicon recess in the silicon substrate (100) is less than that of the high-voltage silicon recess in the silicon substrate (100);
the pad oxide layer (105) covers the silicon substrate (100) and the oxide in the silicon recesses.

9. The method for fabricating the integrated structure of a metal-gate MOS transistor according to claim 8, wherein
the depth of the high-voltage silicon recess in the silicon substrate (100) is 400 Å to 500 Å;
the depth of the medium-voltage silicon recess in the silicon substrate (100) is 100 Å to 200 Å.

10. The method for fabricating the integrated structure of a metal-gate MOS transistor according to claim 1, wherein
in step S12, the second interlayer dielectric layer is formed by in-situ steam generation and thermal oxidation.

11. The method for fabricating the integrated structure of a metal-gate MOS transistor according to claim 1, wherein
the high-resistance layer is made of titanium nitride, tantalum nitride, or tungsten nitride.
